(19) United States
(12) Patent Application Publication
(10) Pub. No.: US 2026/0164989 A1
(43) Pub. Date: Jun. 11, 2026

(54) DISPLAY DEVICE

(71) Applicant: Sharp Display Technology Corporation, Kameyama City, Mie (JP)

(72) Inventor: Kazuatsu ITO, Kameyama City, Mie (JP)

(21) Appl. No.: 19/129,167

(22) PCT Filed: Dec. 12, 2022
(86) PCT No.: PCT/JP2022/045632

§ 371 Date: May 12, 2025

(51) Int. Cl. H10K 59/80; H10K 59/126; H10K 59/131; H10K 77/10; H10K 102/00

(52) U.S. Cl. CPC H10K 59/8722; H10K 59/126; H10K 59/131; H10K 59/873; H10K 77/111; H10K 2102/311

(57) ABSTRACT

A display device includes: a base substrate; a thin-film transistor layer provided on the base substrate; a light-emitting-element layer provided on the thin-film transistor layer and included in a display region; a sealing film provided to cover the light-emitting-element layer; a picture-frame region provided around the display region; a terminal unit provided to one end portion of the picture-frame region; and a folding portion provided in the picture-frame region between the terminal unit and the display region and extending in one direction. The picture-frame region toward the folding portion includes: the sealing film having a folding-portion end portion provided between the display region and the folding portion; and a shield layer formed of either an inorganic film or a metal film, and provided below the sealing film to overlap in a plan view with the folding-portion end portion of the sealing film.

### TECHNICAL FIELD

The disclosure relates to a display device.

### BACKGROUND ART

In recent years, light-emitting organic electroluminescent (EL) display devices using organic EL elements have attracted attention as a replacement for liquid crystal display devices. An organic EL display device includes: a display region that displays an image; and a picture-frame region provided around the display region.

For example, Patent Document 1 proposes an organic EL display device including a thin-film transistor substrate having: a circuit layer; a passivation layer; a lower electrode formed for each of the pixels of a display region; an organic material layer in contact with the lower electrode; an upper electrode covering the organic material layer; and a sealing layer covering the entire upper portion above a base material, all of which are provided above the base material. The thin-film transistor substrate has: a display region; and a water blocking region surrounding the display region. For this organic EL display device, a dry-etching technique using a mask is employed to remove the sealing layer found in a peripheral circuit region surrounding the outside of the water blocking region and in a component mounting region. Here, the etching might damage the sealing layer and the passivation layer in the water blocking region, and water might penetrate from the damaged portion into such a component as the circuit layer and cause the wiring to corrode. Hence, the water blocking region has a water blocking layer formed below the sealing layer. The water blocking layer, which is different in composition from the sealing layer, prevents the damage to the water blocking region surrounding the outside of the display region and keeps the wiring from such a problem as corrosion.

### CITATION LIST

### Patent Literature

[Patent Document 1] Japanese Unexamined Patent Application Publication No. 2018-142441

### SUMMARY

### Technical Problems

Some organic EL display devices are flexible. A proposed flexible organic EL display device has organic EL elements formed on a flexible resin substrate. As to the flexible organic EL display device, for example, a proposal is made to fold one end portion of the frame region. Hence, the frame region narrows so that an area occupied with the frame region is reduced in a plan view. In order to fold the frame region at an angle of 180°, a proposal is made for this organic EL display device to have a structure; that is, removing an inorganic film (hereinafter referred to as “thin-film encapsulation (TFE) film”) forming the sealing film around the folding portion.

Here, the TFE film is an inorganic multilayer film (hereinafter also referred to as a “TFE-CVD film”) including a plurality of inorganic films sequentially deposited by, for example, the plasma chemical vapor deposition (CVD). If the TFE-CVD film is patterned not by photolithography but with a CVD mask, an opening end portion of the mask (i.e., a film end portion of the TFE-CVD film) is likely to become unstable in film quality. Such a TFE-CVD film reacts with, for example, water intruding from outside, and could generate such an ionic substance as NH₄⁺. When the ionic substance reaches the wiring immediately below the film end portion of the CVD film; in particular, when the ionic substance reaches a contact portion such as a contact hole for rewiring, corrosion starts to develop from the contact portion. When the corrosion progresses, the wiring might be broken. Note that Patent Document 1 is silent as to an ionic substance generated when the sealing layer deteriorates and the resulting corrosion of the wiring caused by the ionic substance.

The disclosure is conceived in view of the above problems, and sets out to reduce wiring corrosion caused by an ionic substance generated when a film end portion of a sealing film deteriorates.

### Solution to Problem

In order to achieve the above object, a display device according to the disclosure includes: a base substrate; a thin-film transistor layer provided on the base substrate; a light-emitting-element layer provided on the thin-film transistor layer and included in a display region; a sealing film provided to cover the light-emitting-element layer; a picture-frame region provided around the display region; a terminal unit provided to one end portion of the picture-frame region; and a folding portion provided in the picture-frame region between the terminal unit and the display region and extending in one direction. The picture-frame region toward the folding portion includes: the sealing film having a folding-portion end portion provided between the display region and the folding portion; and a shield layer formed of either an inorganic film or a metal film, and provided below the sealing film to overlap in a plan view with the folding-portion end portion of the sealing film.

### Advantageous Effect of Disclosure

The disclosure can reduce wiring corrosion caused by an ionic substance generated when a film end portion of a sealing film deteriorates.

### BRIEF DESCRIPTION OF DRAWINGS

FIG. 1 is a plan view of a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an enlarged plan view of a wiring structure in a picture-frame region included in the organic EL display device according to the first embodiment of the disclosure and provided toward a folding portion.

FIG. 5 is a cross-sectional view of the wiring structure in the picture-frame region included in the organic EL display device according to the first embodiment of the disclosure and provided toward the folding portion. FIG. 5 is viewed along line V-V in FIG. 4.

FIG. 6 is an equivalent circuit diagram of a TFT layer included in the organic EL display device according to the first embodiment of the disclosure.

FIG. 7 is a cross-sectional view of an organic EL layer included in the organic EL display device according to the first embodiment of the disclosure.

FIG. 8 is a cross-sectional view of a wiring structure in a picture-frame region included in an organic EL display device according to a second embodiment of the disclosure and provided toward a folding portion. FIG. 8 corresponds to FIG. 5.

### DESCRIPTION OF EMBODIMENTS

Embodiments of the disclosure will be described in detail below with reference to the drawings. Note that the disclosure shall not be limited to the embodiments below.

### First Embodiment

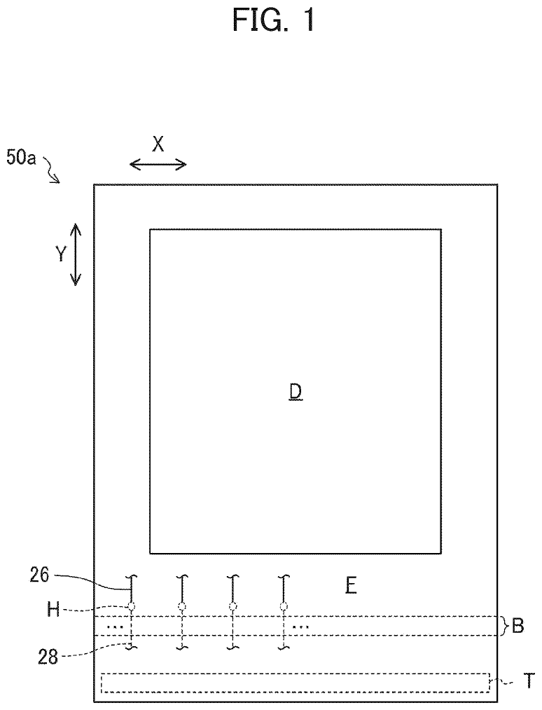

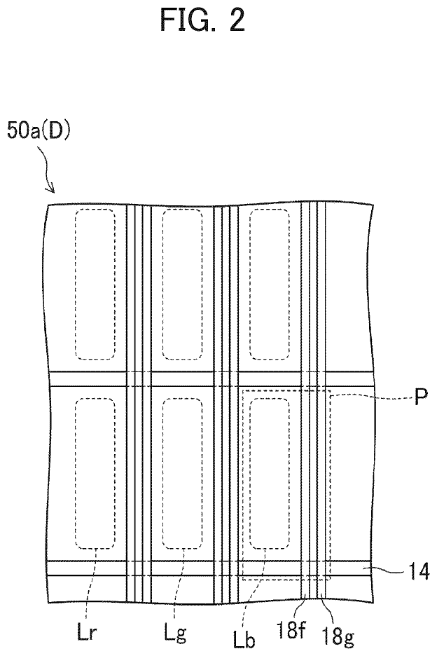

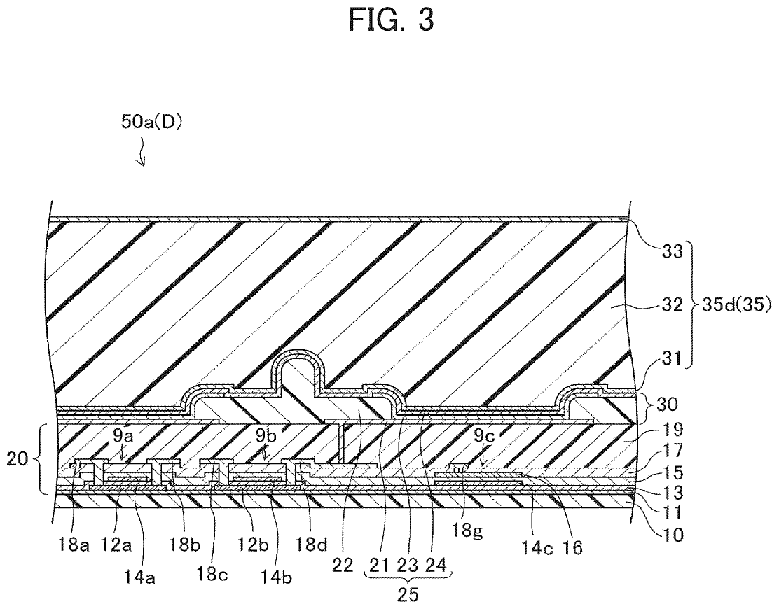

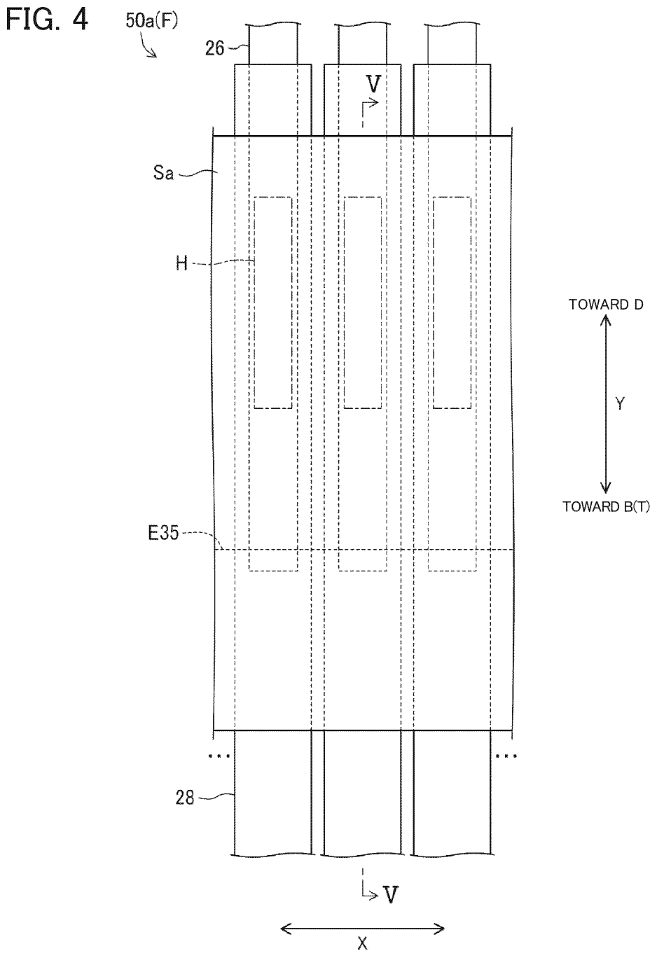

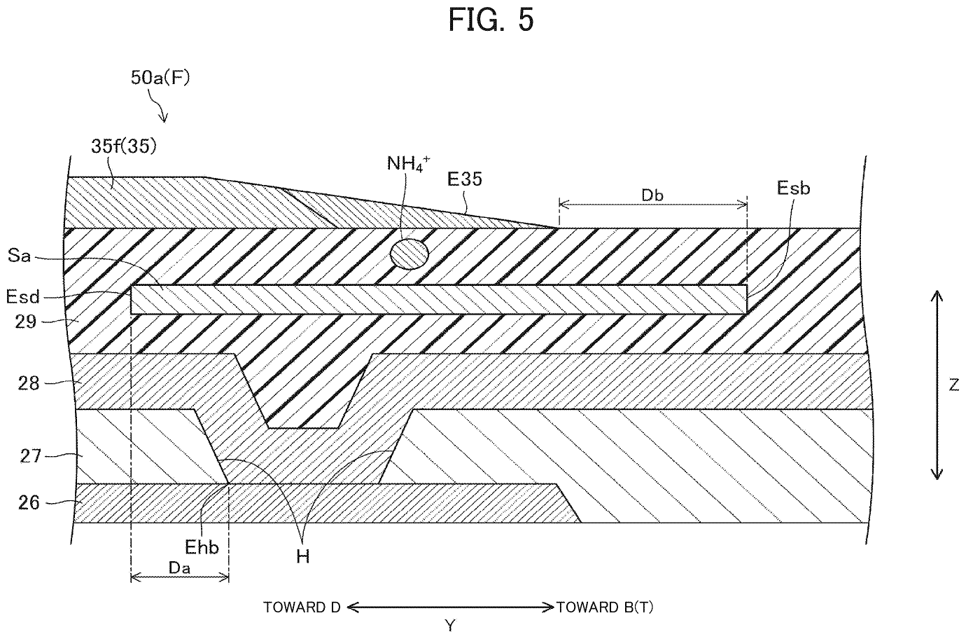

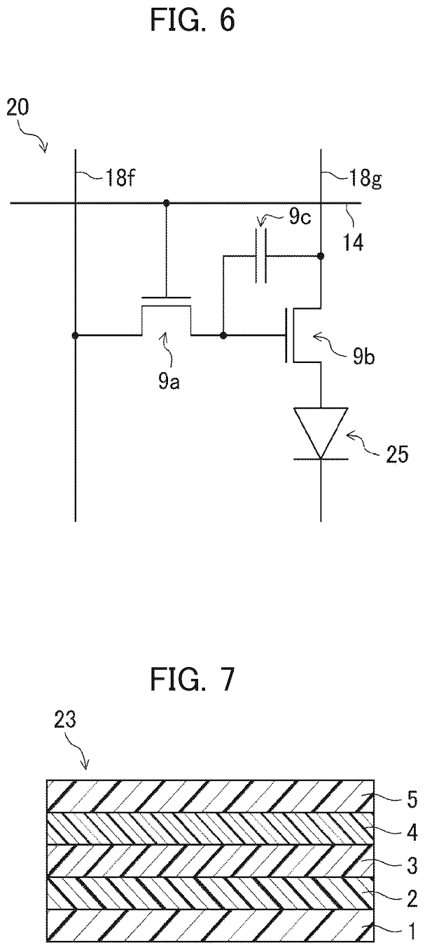

FIGS. 1 to 7 illustrate a first embodiment of a display device according to the disclosure. In the embodiments below, an organic EL display device including an organic EL element is exemplified as a display device including a light-emitting element. Here, FIG. 1 is a plan view of a schematic configuration of an organic EL display device 50a according to this embodiment. FIG. 2 is a plan view of a display region D of the organic EL display device 50a. FIG. 3 is a cross-sectional view of the display region D of the organic EL display device 50a. FIG. 4 is an enlarged plan view of a wiring structure of a picture-frame region F included in the organic EL display device 50a and provided toward a folding portion B. FIG. 5 is a cross-sectional view of the wiring structure of the picture-frame region F included in the organic EL display device 50a and provided toward the folding portion B. FIG. 5 is viewed along line V-V in FIG. 4. FIG. 6 is an equivalent circuit diagram of a TFT layer 20 included in the organic EL display device 50a. FIG. 7 is a cross-sectional view of an organic EL layer 23 included in the organic EL display device 50a. Note that FIG. 4 omits a planarization film 29. FIG. 5 omits a layer below a routed wire 26 and a planarization film 27.

As illustrated in FIG. 1, the organic EL display device 50a includes, for example: the display region D shaped into a rectangle and displaying an image; and the picture-frame region F shaped into a picture frame and provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides. As to the organic EL display device 50a, a first direction X (see FIGS. 1 and 4), a second direction Y (see FIGS. 1, 4, and 5), and a third direction Z (see FIG. 5) are defined. The first direction X is in parallel with a surface of a resin substrate 10 to be described later. The second direction Y is perpendicular to the first direction X and in parallel with the surface of the resin substrate 10. The third direction Z (see FIG. 5) is perpendicular to the first direction X and the second direction Y.

The display region D illustrated in FIG. 2 includes a plurality of subpixels P arranged in a matrix. Moreover, in the display region D, as illustrated in FIG. 2, for example, subpixels P having red light-emitting regions Lr for presenting red, subpixels P having green light-emitting regions Lg for presenting green, and subpixels P having blue light-emitting regions Lb for presenting blue are provided side by side. Note that, in the display region D, for example, neighboring three subpixels P each having one of a red light-emitting region Lr, a green light-emitting region Lg, and a blue light-emitting region Lb constitute one pixel. Note that the subpixels P may be arranged in any given manner such as, for example, a PenTile Matrix or a stripe.

The picture-frame region F has one end portion (a lower end portion in FIG. 1) provided with a terminal unit T extending in one direction (i.e., in the first direction X; that is, a horizontal direction in FIG. 1). Furthermore, as illustrated in FIG. 1, the picture-frame region F includes the folding portion B between the terminal unit T and the display region D. The folding portion B, extending in one direction (in the first direction X), is, for example, foldable at an angle of 180° (in a U-shape) around a folding axis in the first direction X.

As illustrated in FIG. 3, the organic EL display device 50a includes: the resin substrate 10 provided to serve as a base substrate; a thin-film-transistor (hereinafter also referred to as “TFT”) layer 20 provided on the resin substrate 10; an organic-EL-element layer 30 provided to serve as a light-emitting-element layer included in the display region D, and a sealing film 35 provided on the organic-EL-element layer 30. Hereinafter, the sealing film 35 provided in the display region D is also referred to as a “sealing film 35d”.

The resin substrate 10 is made of, for example, such a material as polyimide resin.

The TFT layer 20 illustrated in FIG. 3 includes: a base coat film 11 provided on the resin substrate layer 10; a plurality of first TFTs 9a, a plurality of second TFTs 9b, and a plurality of capacitors 9c, each of which is provided on the base coat film 11 for a corresponding one of the subpixels P; and a planarization film 19 provided above the first TFTs 9a, the second TFTs 9b, and the capacitors 9c. Here, the TFT layer 20 illustrated in FIG. 3 includes: the base coat film 11; semiconductor layers 12a and 12b; a gate insulating film 13; a gate line 14 (see FIG. 2); gate electrodes 14a and 14b; a first wiring layer such as a lower conductive layer 14c; a first interlayer insulating film 15; a second wiring layer such as an upper conductive layer 16; a second interlayer insulating film 17; a third wiring layer such as a source line 18f (see FIG. 2), source electrodes 18a and 18c, drain electrodes 18b and 18d, and a power supply line 18g; and the planarization film 19, all of which are sequentially stacked on top of another above the resin substrate 10. Furthermore, as illustrated in FIGS. 2 and 6, the TFT layer 20 includes a plurality of the gate lines 14 extending in parallel with one another in the horizontal direction in the drawings. Moreover, as illustrated in FIGS. 2 and 6, the TFT layer 20 includes a plurality of the source lines 18f extending in a direction intersecting with (perpendicular to) the plurality of gate lines 14; that is, extending in parallel with one another in the vertical direction in the drawings. In addition, as illustrated in FIGS. 2 and 6, the TFT layer 20 includes a plurality of the power supply lines 18g extending in parallel with one another in the vertical direction in the drawings. Note that, as illustrated in FIG. 2, the power supply lines 18g and the source lines 18f are provided side by side. Moreover, in the TFT layer 20, as illustrated in FIG. 6, each subpixel P includes: a first TFT 9a; a second TFT 9b; and a capacitor 9c.

Each of the base coat film 11, the gate insulating film 13, the first interlayer insulating film 15, and the second interlayer insulating film 17 is an inorganic monolayer insulating film made of such a substance as, for example, silicon nitride (SiNₓ: x is a positive number), silicon oxide (SiO₂), or silicon oxynitride (SiON). Alternatively, each film is an inorganic multilayer insulating film made of these substances. Each of the semiconductor layers 12a and 12b is, for example, a low-temperature-polysilicon film or an In—Ga—Zn—O-based oxide semiconductor film. Each of the first wiring layer, the second wiring layer, and the third wiring layer is, for example, either a metal monolayer film made of such a metal as molybdenum (Mo), titanium (Ti), aluminum (Al), copper (Cu), or tungsten (W), or a metal multilayer film made of such metals as Mo (an upper layer)/Al (a middle layer)/Mo (a lower layer), Ti/Al/Ti, Al (an upper layer)/Ti (a lower layer), Cu/Mo, or Cu/Ti. Note that either the first wiring layer or the second wiring layer is preferably formed of a metal monolayer film made of Mo, or a metal multilayer film of Mo/Al/Mo or Cu/Mo containing Mo. The third wiring layer is preferably formed of a metal multilayer film such as Ti/Al/Ti.

The first TFT 9a and the second TFT 9b are p-type TFTs including the semiconductor layers 12a and 12b doped with impurities such as boron. The semiconductor layers 12a and 12b will be described later.

As illustrated in FIG. 6, in each subpixel P, the first TFT 9a is electrically connected to the corresponding gate line 14 and source line 18f. Furthermore, as illustrated in FIG. 3, the first TFT 9a includes: the semiconductor layer 12a; the gate insulating film 13; a gate electrode 14a; the first interlayer insulating film 15; the second interlayer insulating film 17; and the source electrode 18a and the drain electrode 18b, all of which are sequentially provided above the base coat film 11. Here, as illustrated in FIG. 3, the semiconductor layer 12a is shaped into an island shape and provided on the base coat film 11. For example, the semiconductor layer 12a includes a channel region, a source region, and a drain region. Moreover, as illustrated in FIG. 3, the gate insulating film 13 is provided to cover the semiconductor layer 12a. In addition, as illustrated in FIG. 3, the gate electrode 14a is provided on the gate insulating film 13 to overlap with the channel region of the semiconductor layer 12a. Furthermore, as illustrated in FIG. 3, the first interlayer insulating film 15 and the second interlayer insulating film 17 are sequentially provided to cover the gate electrode 14a. Moreover, as illustrated in FIG. 3, the source electrode 18a and the drain electrode 18b are spaced apart from each other on the second interlayer insulating film 17. In addition, as illustrated in FIG. 3, the source electrode 18a and the drain electrode 18b are respectively and electrically connected to the source region and the drain region of the semiconductor layer 12a through respective contact holes formed in a multilayer film including the gate insulating film 13, the first interlayer insulating film 15, and the second interlayer insulating film 17.

As illustrated in FIG. 6, in each subpixel P, the second TFT 9b is electrically connected to the corresponding first TFT 9 a and power supply line 18g. Furthermore, as illustrated in FIG. 3, the second TFT 9b includes: the semiconductor layer 12b; the gate insulating film 13; a gate electrode 14b; the first interlayer insulating film 15; the second interlayer insulating film 17; and the source electrode 18c and the drain electrode 18d, all of which are sequentially provided above the base coat film 11. Here, as illustrated in FIG. 3, the semiconductor layer 12b is shaped into an island shape and provided on the base coat film 11. For example, the semiconductor layer 12b includes a channel region, a source region, and a drain region. Moreover, as illustrated in FIG. 3, the gate insulating film 13 is provided to cover the semiconductor layer 12b. Furthermore, as illustrated in FIG. 3, the gate electrode 14b is provided on the gate insulating film 13 to overlap with the channel region of the semiconductor layer 12b. In addition, as illustrated in FIG. 3, the first interlayer insulating film 15 and the second interlayer insulating film 17 are sequentially provided to cover the gate electrode 14b. Moreover, as illustrated in FIG. 3, the source electrode 18c and the drain electrode 18d are spaced apart from each other on the second interlayer insulating film 17. Furthermore, as illustrated in FIG. 3, the source electrode 18c and the drain electrode 18d are respectively and electrically connected to the source region and the drain region of the semiconductor layer 12b through respective contact holes formed in the multilayer film including the gate insulating film 13, the first interlayer insulating film 15, and the second interlayer insulating film 17.

Note that, in this embodiment, the first TFTs 9a and the second TFTs 9b are, for example, top gate TFTs. Alternatively, the first TFTs 9a and the second TFTs 9b may be bottom gate TFTs.

As illustrated in FIG. 6, in each subpixel P, the capacitor 9c is electrically connected to the corresponding first TFT 9a and power supply line 18g. Here, as illustrated in FIG. 3, the capacitor 9c includes: the lower conductive layer 14c formed of the same material as, and in the same layer as, the second gate electrodes 14a and 14b; the first interlayer insulating film 15 provided to cover the lower conductive layer 14c; and the upper conductive layer 16 provided on the first interlayer insulating film 15 to overlap with the lower conductive layer 14c. Note that the upper conductive layer 16 in FIG. 3 is electrically connected to the power supply line 18g through a contact hole formed in the second interlayer insulating film 17.

The planarization film 19 (hereinafter also referred to as a “first planarization film 19”) has a flat surface in the display region D. The planarization film 19 is made of such a material as, for example, an organic resin material such as polyimide resin or acrylic resin, or a polysiloxane-based spin-on-glass (SOG) material.

As illustrated in FIG. 3, the organic-EL-element layer 30 includes a plurality of organic EL elements 25. The organic EL elements 25, serving as a plurality of light-emitting elements, are arranged in a matrix so as to correspond to the plurality of respective subpixels P.

As illustrated in FIG. 3, the organic EL elements 25 include: a plurality of first electrodes 21 sequentially provided on the first planarization film 19; a plurality of the organic EL layers 23 provided on the first electrode 21 for a corresponding one of the subpixels P; and a second electrode 24 provided on the organic EL layer 23 in common to the plurality of subpixels P. Furthermore, as illustrated in FIG. 3, the organic EL elements 25 are covered with the sealing film 35.

The first electrodes 21 illustrated in FIG. 3 are arranged on the first planarization film 19 in a matrix so that each of the first electrodes 21 is provided for a corresponding one of the plurality of subpixels P. Furthermore, each of the first electrodes 21 illustrated in FIG. 3 is electrically connected to the drain electrode 18d (or the source electrode 18c) of the second TFT 9b through a contact hole formed in the first planarization film 19. Moreover, the first electrode 21 has a function of injecting holes into the organic EL layer 23. In addition, the first electrode 21 is formed of a material preferably having a large work function to improve efficiency in injecting the holes into the organic EL layer 23. Here, examples of the material forming the first electrode 21 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). In addition, the first electrode 21 may be made of, for example, an alloy of astatine (At)/astatine oxide (AtO₂). Furthermore, the first electrode 21 may be made of a conductive oxide such as, for example, tin oxide (SnO), zinc oxide (ZnO), indium tin oxide (ITO), or indium zinc oxide (IZO). In addition, the first electrode 21 may be formed of a plurality of layers made of the above materials and stacked on top of another. Note that examples of compound materials having a large work function include indium tin oxide (ITO) and indium zinc oxide (IZO).

The first electrode 21 has a peripheral end portion covered with an edge cover 22 provided in a grid pattern in common to the plurality of subpixels P. Here, exemplary materials of the edge cover 22 include either positive photosensitive resin materials such as polyimide resin, acrylic resin, polysiloxane resin, and novolak resin, or a polysiloxane-based SOG material. As illustrated in FIG. 3, the edge cover 22 has a surface partially protruding upwards in the drawing to serve as a pixel photo spacer shaped into an island shape.

As illustrated in FIG. 3, the organic EL layers 23 are arranged on the respective first electrodes 21 and provided in a matrix to correspond to the plurality of respective subpixels P. Here, as illustrated in FIG. 10, each of the organic EL layers 23 includes: a hole injection layer 1; a hole transport layer 2; a light-emitting layer 3, an electron transport layer 4, and an electron injection layer 5, all of which are sequentially provided above the first electrode 21.

The hole injection layer 1 is also referred to as an anode buffer layer. The hole injection layer 1 has a function of approximating energy levels between the first electrode 21 and the organic EL layer 23 to improve efficiency in injecting the holes from the first electrode 21 into the organic EL layer 23. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the first electrode 21 to the organic EL layer 23. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are injected respectively from the first electrode 21 and the second electrode 24, and recombine together, when a voltage is applied with the first electrode 21 and the second electrode 24. Here, the light-emitting layer 3 is formed of a material having high light emission efficiency. Examples of the material forming the light-emitting layer 3 include a metal oxinoid compound [8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzthiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 24 and the organic EL layer 23 to improve efficiency in injecting the electrons from the second electrode 24 into the organic EL layer 23. Such a function can decrease a drive voltage of the organic EL element 25. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 24 is provided to cover each organic EL layer 23 and the edge cover 22. Moreover, the second electrode 24 has a function of injecting the electrons into the organic EL layer 23. Furthermore, the second electrode 24 is formed of a material preferably having a small work function to improve efficiency in injecting the electrons into the organic EL layer 23. Here, examples of the material forming the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru,) manganese (Mn), indium (In), magnesium (Mg), lithium (Li), ytterbium (Yb), and lithium fluoride (LiF). Moreover, the second electrode 24 may be formed of an alloy such as, for example, magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), or lithium fluoride (LiF)/calcium (Ca)/aluminum (Al). Furthermore, the second electrode 24 may be formed of a conductive oxide such as tin oxide (SnO), zinc oxide (ZnO), indium tin oxide (ITO), or indium zinc oxide (IZO). In addition, the second electrode 24 may be formed of a plurality of layers made of the above materials and stacked on top of another. Note that examples of the material having a small work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 3, the sealing film 35d is provided on the organic EL element layer 30 to cover each of the organic EL elements 25. Here, as illustrated in FIG. 3, the sealing film 35d includes: a first inorganic sealing film 31 provided to cover the second electrode 24; an organic sealing film 32 provided on the first inorganic sealing film 31; and a second inorganic sealing film 33 provided to cover the organic sealing film 32. The sealing film 35d has a function of protecting the organic EL layer 23 from such substances as water and oxygen. Here, the first inorganic sealing film 31 and the second inorganic sealing film 33 are made of, for example, inorganic materials such as silicon oxide (SiO₂), aluminum oxide (Al₂O3), a silicon nitride (SiNₓ: x is a positive number) such as trisilicon tetranitride (Si₃N₄), and silicon carbonitride (SiCN). Moreover, the organic sealing film 32 is made of, for example, organic materials such as acrylic resin, polyurea resin, parylene resin, polyimide resin, and polyamide resin.

In addition, in the organic EL display device 50a illustrated in FIGS. 1, 4 and 5, the picture-frame region F toward the folding portion B includes: a plurality of routed wires 26 provided above the TFT layer 20; a planarization film 27 (hereinafter also referred to as a “second planarization film 27”) provided to cover the plurality of routed wires 26; a contact hole H provided in the second planarization film 27; a plurality of folding wires 28 provided on the second planarization film 27; an upper planarization film 29 (hereinafter also referred to as a “third planarization film 29”) provided to cover the plurality of folding wires 28; and the sealing film 35 provided on the third planarization film 29. Hereinafter, the sealing film 35 provided in the picture-frame region F is also referred to as a “sealing film 35f”.

The routed wires 26 are wires routed from the display region D to the picture-frame region F toward the folding portion B. As illustrated in FIG. 1, the plurality of routed wires 26 is provided to extend in the second direction Y from the display region D toward the folding portion B. The routed wires 26 are formed of, for example, the same material as, and in the same layer as, either the first wiring layer (such as the gate line 14, the gate electrodes 14a and 14b, and the lower conductive layer 14c) or the second wiring layer (such as the upper conductive layer 16). The first wiring layer and the second wiring layer are provided to the TFT layer 20 included in the display region D. The routed wires 26 routed from the first wiring layer are provided on the first interlayer insulating film 15 included in the TFT layer 20. The routed wires 26 routed from the second wiring layer are provided on the second interlayer insulating film 17 included in the TFT layer 20. Note that the routed wires 26 may be provided on a layer formed of the same material as, but in a different layer from, either the first wiring layer or the second wiring layer. For example, the routed wires 26 may be provided on the first planarization film 19. As illustrated in FIGS. 4 and 5, the routed wires 26 have folding-portion-B end portions. The folding-portion-B end portions are electrically connected to the folding wires 28 through contact holes H to be described later. Note that the routed wires 26 are preferably formed of a metal monolayer film made of Mo, or a metal multilayer film made of Mo/Al/Mo or Cu/Mo containing Mo.

As illustrated in FIG. 5, the second planarization film 27 is provided above the plurality of routed wires 26 and the TFT layer 20 (either the first interlayer insulating film 15 or the second interlayer insulating film 17), so as to cover the plurality of routed wires 26. The second planarization film 27 has a flat surface in the picture-frame region F toward the folding portion B. For example, the second planarization film 27 is formed of the same material as the first planarization film 19.

As illustrated in FIG. 5, the contact hole H is formed in, and penetrates, the second planarization film 27. The contact hole H is formed for each of the routed wires 26 to at least partially expose the folding-portion-B end portion of the routed wire 26. The contact hole His a portion (a contact portion) to connect together the routed wire 26 (i.e., the folding-portion-B end portion of the routed wire 26) and a folding wire 28 (i.e., a display-region-D end portion of the folding wire 28). As illustrated in FIG. 1, the contact holes H are formed in the picture-frame region F proximate to the folding portion B (i.e., toward the display region D with respect to the folding portion B).

As illustrated in FIG. 1, the folding wires 28 are arranged in the folding portion B so as to electrically connect the routed wires 26 to the terminal unit T (i.e., to respective terminals of the terminal unit T). As illustrated in FIG. 1, the plurality of folding wires 28 is provided to extend in the second direction Y from the proximity of the folding portion B (toward the display region D) toward the terminal unit T. As illustrated in FIGS. 4 and 5, each of the folding wires 28 (i.e., the display-region-D end portion of the folding wire 28) overlaps in a plan view with the corresponding routed wire 26 near the contact hole H, and makes contact with the corresponding routed wire 26 in the contact hole H. Hence, as illustrated in FIGS. 4 and 5, the folding wire 28 is provided above the routed wire 26 and the second planarization film 27. The folding wires 28 are formed of, for example, the same material as, and in the same as, the third wiring layer (such as the source line 18f, the source electrodes 18a and 18c, the drain electrodes 18b and 18d, and the power supply line 18g) provided to the TFT layer 20 included in the display region D. Note that the folding wires 28 are preferably formed of a metal multilayer film such as Ti/Al/Ti.

As illustrated in FIG. 5, the third planarization film 29 is provided above the plurality of folding wires 28 and the second planarization film 27 so as to cover the plurality of folding wires 28. The third planarization film 29 has a flat surface in the picture-frame region F toward the folding portion B. For example, the third planarization film 29 is formed of the same material as the first planarization film 19. Note that the third planarization film 29 is formed of an organic monolayer film or an organic multilayer film, both of which are made of an organic resin material.

As illustrated in FIG. 5, the sealing film 35f is provided on the third planarization film 29. The sealing film 35f is provided along the periphery of the display region D. As illustrated in FIGS. 4 and 5, the sealing film 35f is provided up to the proximity of the folding portion B (i.e., toward the display region D with respect to the folding portion B) in the picture-frame region F toward the folding portion B. Whereas, in order to correspond to the folding structure, the sealing film 35f is not provided in a region overlapping in a plan view with the folding portion B (i.e., in the picture-frame region F provided toward the folding portion B and including the folding portion B). In other words, the sealing film 35f has an folding-portion-B end portion (hereinafter also referred to as a “film end portion”) E35 provided between the display region D and the folding portion B. The film end portion E35 of the sealing film 35f is formed in the proximity of the folding portion B. Note that, as illustrated in FIG. 5, in the organic EL display device 50a, the film end portion E35 of the sealing film 35f and the contact hole H overlap with each other in a plan view. That is, the contact hole H is disposed immediately below the film end portion E35.

Furthermore, the sealing film 35f is made of an inorganic multilayer film formed of the same material as, and in the same layer as, the first inorganic sealing film 31 and the second inorganic sealing film 33 included in the sealing film 35d. Specifically, the sealing film 35f is an inorganic film (e.g., a TFE film) included in the sealing film in the picture-frame region F. For example, the sealing film 35f is formed of an inorganic multilayer film including a plurality of inorganic films sequentially deposited by the plasma CVD (i.e., a TFE-CVD film). Hence, the film end portion E35 of the sealing film 35f is an end portion corresponding to one side of the opening end portion of the CVD mask (i.e., an end portion of the TFE-CVD film). This film end portion E35 is likely to become unstable in film quality. When reacting with water intruding from, for example, outside, the film end portion E35 hydrolyzes and generates such an ionic substance as NH₄⁺. The reason why the film quality of the film end portion E35 is likely to be unstable is possibly because the CVD film, which is usually deposited after formation of the organic EL element 25 included in the organic EL element layer 30, is deposited at a low temperature. Note that the first inorganic sealing film 31 that is a layer (i.e., a first CVD film) below the sealing film 35f is preferably formed of an inorganic material containing silicon oxynitride (SiON) as a main component. The second inorganic sealing film 33 that is a layer above the sealing film 35f is preferably formed of an inorganic material containing silicon nitride (SiNₓ: x is a positive number) as a main component. Note that, in the Description, the term “main component” means a component contained in a constituent material in an amount exceeding 50% by mass.

Here, as illustrated in FIGS. 4 and 5, the organic EL display device 50a of this embodiment includes, in the picture-frame region F toward the folding portion B, a shield layer Sa provided in an entire region including: a lower layer below the sealing film 35f (in particular, the film end portion E35 of the sealing film 35f) corresponding to the opening end portion of the CVD mask; and an upper layer above the contact hole H. For example, if the third planarization film 29 includes two or more stacked films, the shield layer Sa is provided between the stacked films of the third planarization film 29. Alternatively, if the third planarization film 29 includes a single film, the shield layer Sa is provided between the third planarization film 29 and the sealing film 35f.

As illustrated in FIGS. 4 and 5, the shield layer Sa is provided in a region in which the film end portion E35 of the sealing film 35f and the contact hole H overlap with each other in a plan view. Specifically, the shield layer Sa overlaps in a plan view with both the film end portion E35 of the sealing film 35f and the contact hole H.

Furthermore, as illustrated in FIG. 4, the shield layer Sa is shaped into a strip shape in a plan view in the first direction X in which the folding portion B extends, so as to cover the plurality of contact holes H adjacent to each other. The strip-shaped shield layer Sa is sandwiched between the plurality of contact holes H and the film end portion E35 of the sealing film 35f. Hence, even if the film end portion E35, which is unstable in film quality, reacts with a substance such as water intruding from outside and generates an ionic substance such as NH₄⁺ (see FIG. 5), such features reduce the risk that the ionic substance travels around the shield layer Sa and reaches the contact holes H.

The stirp-shaped shield layer Sa has any given length (i.e., a dimension in the first direction X). The length may be determined appropriately in accordance with the number of the contact holes H. Preferably, the shield layer Sa has a length to cover all the contact holes H. Note that, in this embodiment, the shield layer Sa is shaped into, but not limited to, a striped shape in a plan view. In view of reducing a crack to be formed in folding, the shield layer Sa may be shaped into a discontinued island shape provided in the first direction X, so as to overlap with, for example, the contact holes H. However, in view of keeping an ionic substance from traveling around into the contact holes H, the shield layer Sa is shaped preferably into a strip shape in a plan view.

As illustrated in FIG. 5, as to a width (i.e., a dimension in the second direction Y) of the shield layer Sa shaped into either a strip shape or an island shape in a plan view, in view of preventing an ionic substance, generated from the film end portion E35 of the sealing film 35f, from traveling around toward each of the contact holes H, a distance Da toward the display region D between an end Esd of the shield layer Sa and an end Ehd of the contact hole His, for example, 1 μm or longer and 300 μm or shorter. Furthermore, a distance Db toward the folding portion B (i.e., the terminal unit T) between the film end portion E35 of the sealing film 35f (i.e., a distal end of the sealing film 35f) and an end Esb of the shield layer Sa is, for example, 1 μm or longer and 300 μm or shorter. The shield layer Sa having an excessive area causes such a problem as a crack. Hence, the shield layer Sa satisfies preferably either the distance Da or the distance Db, and, more preferably, both the distance Da and the distance Db.

Note that the shield layer Sa has any given thickness (i.e., a dimension in the third direction Z). The thickness may be determined appropriately in accordance with a thickness of an inorganic insulating film or a metal film to be described later.

The shield layer Sa may be made of a monolayer film or a multilayer film formed of an inorganic insulating film or a metal film.

The shield layer Sa formed of an inorganic insulating film (hereinafter also referred to as an “inorganic shield layer”) is preferably a monolayer film or a multilayer film made of, for example, silicon nitride (SiNₓ: x is a positive number), silicon oxide (SiO₂), silicon oxynitride (SiON), and more preferably, a monolayer film or a multilayer film made of silicon nitride. The inorganic shield layer Sa may be formed of, for example, an inorganic insulating film newly deposited and patterned. Here, the inorganic shield layer Sa can be deposited at a higher temperature than the CVD film forming the sealing film 35f. Hence, the film quality of the inorganic shield layer Sa is readily stabilized.

The shield layer Sa formed of a metal film (hereinafter also referred to as a “metal shield layer”) formed of the same material as, and in the same layer as, for example, a fourth wiring layer and the first electrode 21. The fourth wiring layer is provided above the third wiring layer (i.e., such a layer as a conductive layer between the third wiring layer and the first electrode 21), and the first electrode 21 is provided above the fourth wiring layer. Here, either the fourth wiring layer or the first electrode 21 is routed from the display region D to the picture-frame region F toward the folding portion B. Note that the metal shield layer is preferably formed of a metal multilayer film such as Ti/Al/Ti. Furthermore, the metal shield layer Sa may be formed of, for example, a metal film newly deposited and patterned.

A negative voltage is applied to the shield layer Sa so that the shield layer Sa attracts NH₄⁺ and further prevents NH₄⁺ from traveling around toward the contact hole H. From such a viewpoint, the shield layer Sa is preferably the metal shield layer Sa. Examples of the technique to apply a negative voltage to the metal shield layer Sa includes a technique to electrically connect together the shield layer Sa and a negative voltage wire disposed near the shield layer Sa.

The above organic EL display device 50a displays an image as follows: In each of the subpixels P, a gate signal is input to the first TFT 9a through the gate line 14 to turn ON the first TFT 9a. Through the source line 18f, a data signal is written to the gate electrode 14b of the second TFT 9b and the capacitor 9c. A current based on a gate voltage of the second TFT 9b is supplied from the power supply line 18g to the organic EL layer 23, and the light-emitting layer 3 of the organic EL layer 23 emits light to display an image. Note that, in the organic EL display device 50a, even if the first TFT 9a turns OFF, the gate voltage of the second TFT 9b is held in the capacitor 9c. Hence, the light-emitting layer 3 keeps emitting light until a gate signal in the next frame is input.

Described next will be a method for producing the organic EL display device 50a of this embodiment. The method for producing the organic EL display device 50a of this embodiment includes: a TFT-layer forming step; a shield-layer forming step; an organic-EL-element-layer forming step; and a sealing-film forming step.

### Tft-Layer Forming Step

For example, such features as the base coat film 11, the first TFT 9a, the second TFT 9b, the capacitor 9c, and the first planarization film 19 are formed by a known technique on the surface of the resin substrate 10 formed on a glass substrate. Hence, the TFT layer 20 is formed. Here, when the first wiring layer (such as the gate line 14, the gate electrodes 14a and 14b, and the lower conductive layer 14c) or the second wiring layer (such as the upper conductive layer 16) is formed, the first wiring layer or the second wiring layer is routed to the picture-frame region F toward the folding portion B. Hence, the routed wire 26 is also formed. Furthermore, when the third wiring layer (such as the source line 18f, the source electrodes 18a and 18c, the drain electrodes 18b and 18d, and the power supply line 18g) is formed, the second planarization film 27, the contact hole H, and the folding wire 28 are also formed in the picture-frame region F toward the folding portion B. For example, first, the second planarization film 27 is formed in the same manner as, and of the same material as, the first planarization film 19. Next, the contact hole H is formed by a known technique in a region included in the second planarization film 27 and overlapping in a plan view with a folding-portion-B end portion of the routed wire 26. Here, the contact hole H is formed to reach the folding-portion-B end portion of the routed wire 26, so as to expose an upper face of the end portion. Finally, above the second planarization film 27 and the contact hole H, the folding wire 28 is formed of the same material as the third wiring layer.

### Shield-Layer Forming Step

In the picture-frame region F toward the folding portion B, the third planarization film 29 and the shield layer Sa are formed. For example, first, a lower planarization film is formed in the same manner as, and of the same material as, the first planarization film 19, so as to cover the folding wire 28. The lower planarization film forms the third planarization film 29 including two layers. Subsequently, when the fourth wiring layer (such as a conductive layer between the third wiring layer and the first electrode 21) or the first electrode 21 is formed on the lower planarization film at the TFT-layer forming step, the shield layer Sa is formed of the same material as the fourth wiring layer and the first electrode 21. Note that the shield layer Sa may be formed on a substrate surface provided with the lower planarization film. A new metal film or a new inorganic insulating film may be deposited and patterned to form the shield layer Sa. Here, the shield layer Sa is formed in an entire region overlapping in a plan view with both: the plurality of contact holes H; and an end portion (i.e., the film end portion E35 of the sealing film 35f) corresponding to one side of the opening end portion of the CVD mask (i.e., an end portion of the TFE-CVD film) at the sealing-film forming step to be described later.

### Organic-EL-Element-Layer Forming Step

In the display region D, on the first planarization film 19 of the TFT layer 20 formed at the TFT-layer forming step, the first electrode 21, the edge cover 22, the organic EL layer 23 (including the hole injection layer 1, the hole transport layer 2, the light-emitting layer 3, the electron transport layer 4, and the electron injection layer 5), and the second electrode 24 are formed using a known technique so that the organic EL element 25 is formed. Hence, the organic-EL-element layer 30 is formed.

### Sealing-Film Forming Step

First, on the substrate surface provided with the organic-EL-element layer 30 formed at the organic-EL-element-layer forming step, an inorganic insulating film such as, for example, a silicon nitride film, a silicon oxide film, or a silicon oxynitride film is deposited to cover each of the organic EL elements 25 by the plasma CVD using a CMM as a vapor deposition mask. Hence, the first inorganic sealing film 31 is formed. Then, on the first inorganic sealing film 31, an organic resin material such as acrylic resin is deposited by, for example, inkjet printing. Hence, the organic sealing film 32 is formed. After that, an inorganic insulating film such as, for example, a silicon nitride film, a silicon oxide film, or a silicon oxynitride film is deposited to cover the organic sealing film 32 by the plasma CVD using a CMM as a vapor deposition mask, so as to form the second inorganic sealing film 33. Hence, the sealing film 35 is formed. Through these steps, the sealing film 35d is formed in the display region D to include the first inorganic sealing film 31, the organic sealing film 32, and the second inorganic sealing film 33, all of which are sequentially stacked on top of another.

Whereas, the sealing film 35f is formed in the picture-frame region F to include the first inorganic sealing film 31 and the second inorganic sealing film 33 except for the organic sealing film 32. The first inorganic sealing film 31 and the second inorganic sealing film 33 are sequentially stacked on top of another. Here, in order to correspond to the folding structure of the picture-frame region F, the sealing film 35f is not deposited in the picture-frame region F provided toward the folding portion B and including the folding portion B. Specifically, in the picture-frame region F toward the folding portion B, one side of the opening end portion of the CVD mask (i.e., an end portion of the TFE-CVD film) is disposed in the proximity of the folding portion B (i.e., toward the display region D with respect to the folding portion B), and the first inorganic sealing film 31 and the second inorganic sealing film 33 are patterned. Hence, the sealing film 35f is formed to have the film end portion E35 positioned to correspond to the one side.

Finally, a protective sheet (not shown) is attached to the substrate surface. After that, a laser beam is emitted from toward the glass substrate of the resin substrate 10, and the glass substrate is removed from a lower surface of the resin substrate 10. To the lower surface of the resin substrate 10 from which the glass substrate is removed, a protective sheet (not shown) is attached. As can be seen, the organic EL display device 50a is successfully produced.

### Advantageous Effects

As described above, the organic EL display device 50a according to this embodiment can achieve the advantageous effects below.
(1) The organic EL display device 50a includes either the inorganic shield layer Sa formed of an inorganic film or the metal shield layer Sa formed of a metal film. In the picture-frame region F toward the folding portion B (i.e., between the display region D and the folding portion B), the inorganic shield layer Sa or the metal shield layer Sa is provided below the sealing film 35f to overlap in a plan view with the film end portion E35 corresponding to one side of the opening end portion of the CVD mask (i.e., an end portion of the TFE-CVD film). These shield layers Sa are sandwiched between the film end portion E35 and the folding wire 28 provided immediately below the film end portion E35 together with, for example, the contact portion (i.e., the contact hole H) for reconnecting the folding wire 28 to the routed wire 26. When the film end portion E3, which is unstable in film quality, hydrolyzes and generates an ionic substance such as NH₄⁺, the shield layers Sa keep the ionic substance from traveling around and reaching, for example, the folding wire 28 and the contact portion. As a result, the organic EL display device 50a can reduce wiring corrosion caused by the ionic substance and produced on, for example, the folding wire 28 and the contact portion. In particular, the wiring corrosion caused by an ionic substance is likely to possibly develop between wires having a large difference in oxidation-reduction potential. For example, the organic EL display device 50a effectively reduces corrosion on a contact portion provided when the routed wire 26 is a Mo wire and the folding wire 28 reconnected to the routed wire 26 is a Ti/Al/Ti wire and on Ti/Al/Ti wires.
(2) The organic EL display device 50a uses the metal shield layer Sa to apply a negative voltage to the metal shield layer Sa. The charged metal shield layer Sa attracts an ionic substance and further keeps the ionic substance from reaching, for example, the folding wire 28 and the contact portion.
(3) The organic EL display device 50a has the film end portion E35 of the sealing film 35f and the contact portion overlapping with each other in a plan view. Thus, the inorganic shield layer Sa or the metal shield layer Sa is provided also above the contact portion. Hence, the organic EL display device 50a can further reduce wiring corrosion caused by the ionic substance and produced on the contact portion.

### Second Embodiment

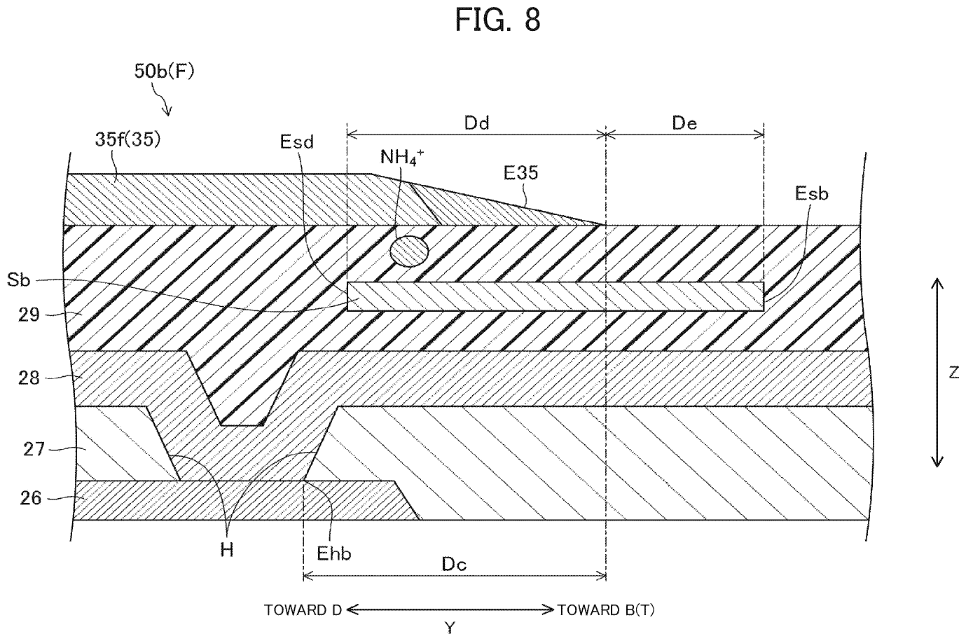

Next, a second embodiment of the disclosure will be described with reference to FIG. 8. FIG. 8 is a cross-sectional view of a wiring structure in the picture-frame region F included in an organic EL display device 50b of this embodiment and provided toward the folding portion B. FIG. 8 corresponds to FIG. 5. Note that FIG. 8 omits a layer below the routed wire 26 and the planarization film 27. The overall configuration of the organic EL display device 50b is the same as that of the organic EL display device 50a according to the first embodiment except for the configuration of the picture-frame region F toward the folding portion B, and a detailed description thereof will be omitted. Furthermore, like reference signs designate identical constituent features between this embodiment and the first embodiment. Such constituent features will not be elaborated upon.

As illustrated in FIG. 8, in the organic EL display device 50b, the film end portion E35 of the sealing film 35f and the contact hole H do not overlap with each other in a plan view. The film end portion E35 and the contact hole H are spaced apart from each other in the second direction Y perpendicular to the first direction X in which the folding portion B extends. Hence, as to the organic EL display device 50b, the position of a shield layer Sb in the second direction Y is different from the position of the shield layer Sa included in the organic EL display device 50a. In the organic EL display device 50a illustrated in FIG. 5, the shield layer Sa is disposed to overlap in a plan view with both the plurality of contact holes H and the film end portion E35 of the sealing film 35f. Whereas, in the organic EL display device 50b illustrated in FIG. 8, the shield layer Sb is disposed immediately below the film end portion E35 to overlap, in a plan view, only with the film end portion E35 of the sealing film 35f. Note that, similar to the shield layer Sa, the shield layer Sb is shaped into a strip shape extending in the first direction X in a plan view, so as to cover the plurality of contact holes H adjacent to each other.

Similar to the shield layer Sa, the shield layer Sb has any given length (i.e., a dimension in the first direction X). The length may be determined appropriately in accordance with the number of the contact holes H. Preferably, the shield layer Sb has a length to cover all the contact holes H.

As illustrated in FIG. 8, in view of preventing an ionic substance, generated from the film end portion E35 of the sealing film 35f, from traveling around toward each of the contact holes H, a distance Dc toward the folding portion B (i.e., the terminal unit T) between an end Ehb of the contact hole H and the film end portion E35 of the sealing film 35f (i.e., a distal end of the sealing film 35 f) is, for example, 100 μm or longer. When the distance Dc is within the range, even if the shield layer Sb is not disposed immediately above the contact hole H, the shield layer Sb keeps an ionic substance such as NH₄⁺, which is generated from the film end portion E35 unstable in film quality (see FIG. 8), from traveling around the shield layer Sb and reaching the contact hole H.

As illustrated in FIG. 8, as to a width (i.e., a dimension in the second direction Y) of the shield layer Sb, a distance Dd toward the display region D between an end Esd of the shield layer Sb and the film end portion E35 of the sealing film 35f (i.e., a distal end of the shield layer 35f) is, for example, 1 μm or longer and 300 μm or shorter. Furthermore, a distance De toward the folding portion B (i.e., the terminal unit T) between the film end portion E35 of the sealing film 35f (i.e., a distal end of the sealing film 35f) and the end Esb of the shield layer Sb is, for example, 1 μm or longer and 300 μm or shorter. The shield layer Sb having an excessive area causes such a problem as a crack. Hence, the shield layer Sb satisfies preferably the distance Dc and either the distance Dd or the distance De, and, more preferably, the distance Dc and both the distance Dd and the distance De (i.e., a distance between the distance Dc to the distance De).

The organic EL display device 50b may be formed with a different patterning process at the shield-layer forming step of the organic EL display device 50a. Specifically, the shield layer Sb may be formed to overlap in a plan view with an end portion (i.e., the film end portion E35 of the sealing film 35f) corresponding to one side of the opening end portion of the CVD mask (i.e., an end portion of the TFE-CVD film) at the sealing-film forming step.

### Advantageous Effects

As described above, the organic EL display device 50b according to this embodiment can achieve the advantageous effects below in addition to the above advantageous effects (1) and (2).
(4) The organic EL display device 50b includes either the inorganic shield layer Sb or the metal shield layer Sb. In the picture-frame region F toward the folding portion B (i.e., between the display region D and the folding portion B), the inorganic shield layer Sb or the metal shield layer Sb is provided below the sealing film 35f to overlap, in a plan view, only with the film end portion E35. These shield layers Sb are sandwiched between the film end portion E35 and the folding wire 28 provided immediately below the film end portion E35. When the film end portion E3, which is unstable in film quality, hydrolyzes and generates an ionic substance such as NH₄⁺, the shield layers Sb keep the ionic substance from traveling around and reaching the folding wire 28. As a result, the organic EL display device 50b can reduce wiring corrosion caused by the ionic substance and produced on the folding wire 28.
(5) The organic EL display device 50b has the shield layer Sb found immediately below the film end portion E35 that generates an ionic substance. Hence, the shield layer Sb keeps the ionic substance from reaching the contact portion (i.e., the contact hole H) spaced apart from, and not overlapping in a plan view with, the film end portion E35. As a result, the organic EL display device 50b can reduce wiring corrosion caused by the ionic substance and produced on, for example, the folding wire 28 and the contact portion.
(6) In the organic EL display device 50b, the distance Dc toward the folding portion B (i.e., the terminal unit T) is defined, for example, 100 μm or longer between the end Ehb of the contact hole H and the film end portion E35 of the sealing film 35f (a distal end of the sealing film 35f). Hence, the organic EL display device 50b can further reduce wiring corrosion caused by the ionic substance and produced on the contact portion.

### Other Embodiments

In each of the above embodiments, the inorganic multilayer film includes four layers of the base coat film, the gate insulating film, the first interlayer insulating film, and the second interlayer insulating film all of which are sequentially stacked on top of another. Alternatively, the inorganic multilayer film may be made of either one layer of the base coat film or two layers of the base coat film and the gate insulating film.

In each of the above embodiments, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Moreover, in each of the above embodiments, the exemplified organic EL display device includes a first electrode as an anode and a second electrode as a cathode. The disclosure can also be applied to an organic EL display device whose multilayer structure of the organic EL layer is inverted, such that the first electrode is a cathode and the second electrode is an anode.

In each of the above embodiments, described as an example is the organic EL display device in which an electrode of a TFT connected to the first electrode is a drain electrode. The disclosure can also be applied to an organic EL display device in which an electrode of a TFT connected to a first electrode is referred to as a source electrode.

In each of the above embodiments, the organic EL display device is a display device. The disclosure is also applicable to display devices including an active-matrix liquid crystal display device.

In each of the embodiments, the organic EL display device is exemplified as a display device. The disclosure shall not be limited to organic EL display devices, and can be applied to flexible display devices. For example, the disclosure can be applied to flexible display devices including quantum-dot light-emitting diodes (QLEDs); that is, light-emitting elements including layers containing quantum dots.

### INDUSTRIAL APPLICABILITY

As described above, the disclosure is useful for a flexible display device.

1. A display device, comprising:
a base substrate;
a thin-film transistor layer provided on the base substrate;
a light-emitting-element layer provided on the thin-film transistor layer and included in a display region;
a sealing film provided to cover the light-emitting-element layer;
a picture-frame region provided around the display region;
a terminal unit provided to one end portion of the picture-frame region; and
a folding portion provided in the picture-frame region between the terminal unit and the display region and extending in one direction,
wherein the picture-frame region toward the folding portion includes:
the sealing film having a folding-portion end portion provided between the display region and the folding portion; and
a shield layer formed of either an inorganic film or a metal film, and provided below the sealing film to overlap in a plan view with the folding-portion end portion of the sealing film.

2. The display device according to claim 1,
wherein the shield layer is shaped into a strip shape in a plan view in a direction in which the folding portion extends.

3. The display device according to claim 1,
wherein the picture-frame region toward the folding portion includes:
a plurality of routed wires routed from the display region;
a planarization film provided to cover the plurality of routed wires;
a plurality of folding wires provided on the planarization film; and
a plurality of contact holes provided in the planarization film and each electrically connecting together one of the plurality of routed wires and one of the plurality of folding wires, and
the plurality of contact holes does not overlap in a plan view with the folding-portion end portion of the sealing film.

4. The display device according to claim 3,
wherein, in a direction perpendicular to the one direction in which the folding portion extends, each of the plurality of contact holes has an end provided toward the folding portion and spaced 100 μm or longer apart from the folding-portion end portion of the sealing film.

5. The display device according to claim 1,
wherein the picture-frame region toward the folding portion includes:
a plurality of routed wires routed from the display region;
a planarization film provided to cover the plurality of routed wires;
a plurality of folding wires provided on the planarization film; and
a plurality of contact holes provided in the planarization film and each electrically connecting together one of the plurality of routed wires and one of the plurality of folding wires,
the plurality of contact holes overlaps in a plan view with the folding-portion end portion of the sealing film, and
the shield layer overlaps with the plurality of contact holes in a plan view.

6. The display device according to claim 3,
wherein the thin-film transistor layer includes: a first wiring layer; and a second wiring layer above the first wiring layer, and
the plurality of routed wires is formed of a same material as, and in a same layer as, either the first wiring layer or the second wiring layer.

7. The display device according to claim 6,
wherein the thin-film transistor layer includes a third wiring layer above the second wiring layer, and
the plurality of folding wires is formed of a same material as, and in a same layer as, the third wiring layer.

8. The display device according to claim 7,
wherein the light-emitting-element layer includes a plurality of light-emitting elements each having a first electrode, and
the shield layer is formed of a same material as, or in a same layer as, either a fourth wiring layer or a metal film, the fourth wiring layer being provided above the third wiring layer and formed between the third wiring layer and the first electrode, and the metal film being provided above the fourth wiring layer and included in the first electrode.

9. The display device according to claim 8,
wherein a negative voltage is applied to the shield layer.

10. The display device according to claim 1,
wherein the picture-frame region toward the folding portion includes
an upper planarization film including either a single layer or a plurality of stacked layers, and provided to cover the plurality of folding wires, and
the shield layer is provided either between the upper planarization film of the single layer and the sealing film, or between the plurality of stacked layers of the upper planarization film.

11. The display device according to claim 1,
wherein the light-emitting-element layer is an organic-electroluminescent-element layer.
